(19) United States
(12) Patent Application Publication
(10) Pub. No.: US 2025/0266336 A1
(43) Pub. Date: Aug. 21, 2025

(54) SEMICONDUCTOR PACKAGE AND METHOD OF MANUFACTURING AND TESTING THE SAME

(71) Applicant: TAIWAN SEMICONDUCTOR MANUFACTURING COMPANY LTD., HSINCHU (TW)

(72) Inventors: CHIH-HSUAN TAI, TAIPEI CITY (TW); HSIANG-TAI LU, HSINCHU COUNTY (TW)

(21) Appl. No.: 18/443,329

(22) Filed: Feb. 16, 2024

(51) Int. Cl. H01L 23/498; H01L 23/00; H01L 25/065

(52) U.S. Cl. CPC H01L 23/49816; H01L 23/49838; H01L 24/08; H01L 24/16; H01L 25/0655; H01L 2224/08146; H01L 2224/08155; H01L 2224/16146; H01L 2224/16157; H01L 2924/1431; H01L 2924/1434; H01L 2924/15311; H01L 2924/182

(57) ABSTRACT

A method for manufacturing and testing a semiconductor package includes receiving a first semiconductor structure having a first side and a second side opposite to the first side, wherein the first semiconductor structure further includes: a first die; a first bump disposed over the first die; a first via adjacent to the first die; and a first molding surrounding the first die, the first bump and the first via. The method further includes disposing a plurality of connectors on the first side, wherein each of the plurality of connectors is electrically connected to at least one of the first bump and the first via; probing the plurality of connectors; and bonding the first semiconductor structure to a second semiconductor structure, wherein the plurality of connectors are disposed between the first semiconductor structure and the second semiconductor structure after the bonding.

### BACKGROUND

The semiconductor industry has experienced rapid growth due to ongoing improvements in integration density of a variety of components (e.g., active components and passive components). To accommodate miniaturized scales of semiconductor devices, various technologies and applications have been developed for wafer-level packaging, involving greater numbers of different components with different functions. The improvements in integration density have resulted from iterative reduction of minimum feature size, allowing more components to be integrated into a given area.

As the demand for smaller electronic devices has increased, a need for more space-efficient and more creative techniques for packaging semiconductor dies has emerged. An example of such packaging systems is package-on-package (PoP) technology. In a PoP device, a top semiconductor package is stacked on top of a bottom semiconductor package to provide a high level of integration and component density. Another example is a chip-on-wafer-on-substrate (CoWoS) structure, where a semiconductor chip is attached to a wafer (e.g., an interposer) to form a chip-on-wafer (CoW) structure. The CoW structure is then attached to a substrate (e.g., a printed circuit board) to form the CoWoS structure. These and other advanced packaging technologies enable production of semiconductor devices with enhanced functionalities and small footprints.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, dimensions of the various features may be arbitrarily increased or reduced for clarity of discussion.

FIG. 1 is a top view of a semiconductor package in accordance with some embodiments of the present disclosure.

FIG. 2 is a cross-sectional view of a portion of a semiconductor package in accordance with some embodiments of the present disclosure.

FIG. 3 is a cross-sectional view of a semiconductor package in accordance with some embodiments of the present disclosure.

FIG. 4 is a cross-sectional view of a semiconductor package in accordance with some embodiments of the present disclosure.

FIG. 5 is a flow diagram of a method for manufacturing and testing a semiconductor package in accordance with some embodiments of the present disclosure.

FIG. 6 is a flow diagram of a method for manufacturing and testing a semiconductor package in accordance with some embodiments of the present disclosure.

FIG. 7 is a flow diagram of a method for manufacturing and testing a semiconductor package in accordance with some embodiments of the present disclosure.

FIGS. 8 to 18 are cross-sectional views of one or more stages of the method for manufacturing and testing a semiconductor package in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard variation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Other features and processes may also be included. For example, testing structures may be included to aid in verification testing of 3D packaging or 3DIC devices. The testing structures may include, for example, test pads formed in a redistribution layer or on a substrate that allows the testing of the 3D packaging or 3DIC, use of probes and/or probe cards, and the like. The verification testing may be performed on intermediate structures as well as a final structure. Additionally, the structures and methods disclosed herein may be used in conjunction with testing methodologies that incorporate intermediate verification of known good dies to increase yields and decrease costs.

In the present disclosure, a semiconductor package and a method of manufacturing and testing a semiconductor package are provided. A semiconductor package includes a first die disposed over a first surface of a first redistribution layer (RDL); a first bump disposed over the first die; a first via disposed over the first RDL and adjacent to the first die and the first bump; a first molding disposed over the first RDL and surrounding the first die, the first bump and the first via; a first bump connector disposed over and electrically connected to the first bump; and a first via connector disposed over and electrically connected to the first via. The semiconductor package further includes a second die disposed over and electrically connected to the first bump connector and the first via connector; a second molding disposed over the first molding and surrounding the second die, the first bump connector and the first via connector; and a plurality of conductive bumps disposed on a second surface of the first RDL opposite to the first surface of the first RDL and electrically connected to the first RDL, the first die and the second die.

A method for manufacturing and testing a semiconductor package includes: receiving a first semiconductor structure having a first side and a second side opposite to the first side, and including a first die, a first bump disposed over the first die, a first via adjacent to the first die, and a first molding surrounding the first die, the first bump and the first via; and disposing a plurality of connectors at the first side, wherein the plurality of connectors are electrically connected to at least one of the first bump and the first via. The method further includes probing the plurality of connectors and bonding the first semiconductor structure to a second semiconductor structure, wherein the plurality of connectors are disposed between the first semiconductor structure and the second semiconductor structure after the bonding. Other features and processes may also be included.

The method of the present disclosure further includes probing the first semiconductor package before disposing the second semiconductor structure on the first semiconductor structure, wherein the probing of the semiconductor package includes the first semiconductor structure and the second semiconductor structure. As a result, the semiconductor package thus formed can be tested at two locations to enable monitoring of an interface robustness, and the manufacturing process may be improved so as to reduce costly scrapping of defective components.

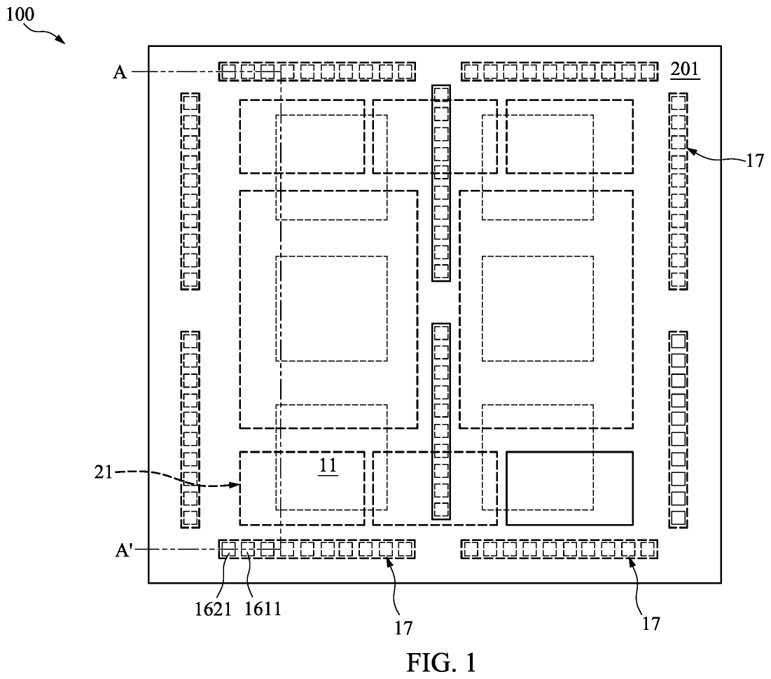

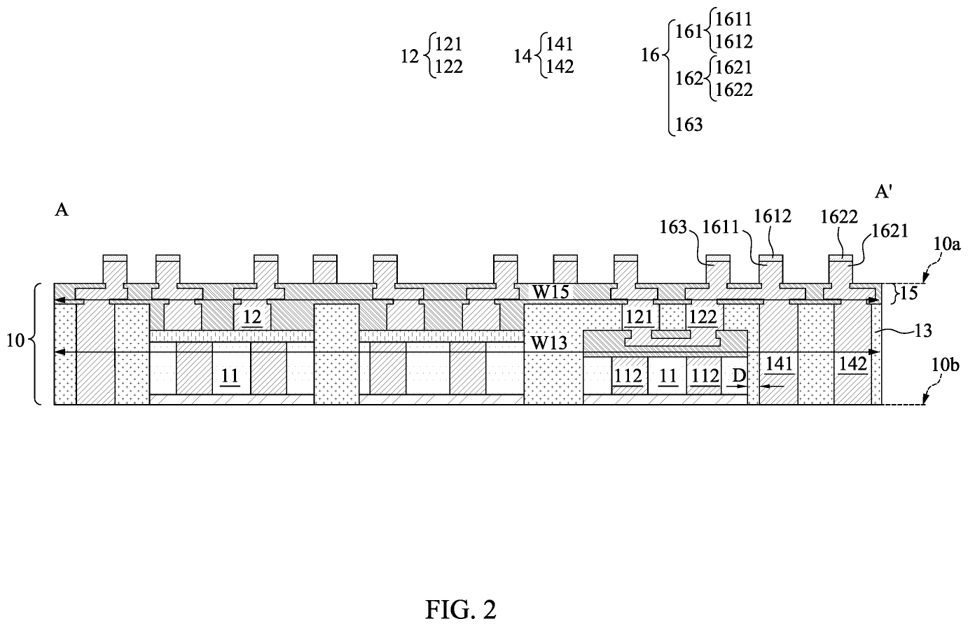

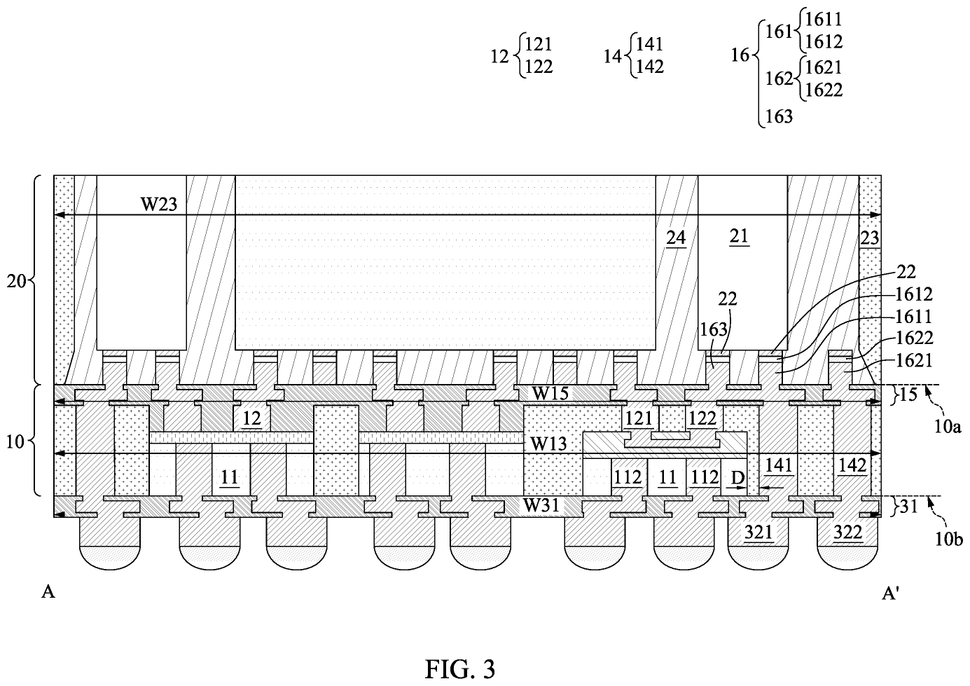

FIG. 1 is a top view of a semiconductor package 100 in accordance with some embodiments of the present disclosure. FIG. 2 is a cross-sectional view of an embodiment of a portion of the semiconductor package 100 along a line A-A′ in FIG. 1. FIG. 3 is a cross-sectional view of another embodiment of a portion of the semiconductor package 100 along the line A-A′ in FIG. 1.

Referring to FIGS. 1, 2 and 3, the semiconductor package 100 includes a first semiconductor structure 10 and a second semiconductor structure 20. In some embodiments, the semiconductor package 100 is a part of a chip-on-wafer-on-substrate (CoWoS) structure.

In some embodiments, the first semiconductor structure 10 has a first side 10a and a second side 10b opposite to the first side 10a. In some embodiments, the first semiconductor structure 10 includes a first die 11, a first bump 12 disposed over the first die 11, a first via 14 adjacent to the first die 11 and the first bump 12, and a first molding 13 surrounding the first die 11, the first bump 12 and the first via 14. In some embodiments, the first semiconductor structure 10 is an interposer.

In some embodiments, the first die 11 is a logic die, which may be a central processing unit (CPU) die, a micro-control unit (MCU) die, an input-output (IO) die, a baseband (BB) die, an application processor (AP) die, or the like. In some embodiments, the first die 11 is a memory die such as a dynamic random-access memory (DRAM) die or a static random-access memory (SRAM) die, or may be another type of die. In some embodiments, a plurality of first dies 11 adjacent to each other are disposed over the carrier substrate 101. In some embodiments, the first die 11 is disposed on and electrically connected to a first redistribution layer (RDL) 31. In some embodiments, the second side 10b of the first semiconductor structure 10 is attached to the first RDL 31.

In some embodiments, each of the first dies 11 includes a plurality of first bumps 12, such as a first bump pad 121 and a second bump pad 122, disposed over the first die 11. Each of the first bumps 12 is electrically connected to a circuitry or an electrical component disposed over or within the corresponding first die 11. In some embodiments, each of the first bumps 12 is electrically connected to a second via 112. In some embodiments, the second via 112 is a local silicon interconnect (LSI). In some embodiments, the first bump pad 121 and the second bump pad 122 are electrically connected. In some embodiments, the first bumps 12 are disposed in a direction away from the carrier substrate 101 or the first RDL 31.

In some embodiments, the first via 14 is disposed adjacent to the first die 11 and the first bump 12. In some embodiments, a distance D between the first die 11 and the first via 14 is greater than 350 nm. In some embodiments, the first via 14 is a through-via. In some embodiments, the first via 14 is disposed on and electrically connected to the first RDL 31. In some embodiments, the first semiconductor structure 10 includes a plurality of first vias 14. In some embodiments, the plurality of first vias 14 are disposed at a peripheral portion of the semiconductor package 100 and surround the first die 11 from a top view perspective. In some embodiments, some of the plurality of first vias 14 are disposed between adjacent pairs of the first dies 11.

In some embodiments, the first via 14 includes a first through via 141 and a second through via 142. In some embodiments, the first through via 141 is disposed adjacent to the first die 11 and the first bump 12. In some embodiments, the distance D between the first die 11 and the first through via 141 is greater than 350 nm. In some embodiments, the first through via 141 is disposed between the first die 11 and the second through via 142.

In some embodiments, the first molding 13 surrounds and encapsulates the first die 11, the first bump 12 and the first via 14. In some embodiments, the first molding 13 is disposed on the first RDL 31. In some embodiments, a bottom surface of the first die 11 is substantially coplanar with a bottom surface of the first molding 13. In some embodiments, a top surface of the first bump 12 is substantially coplanar with a top surface of the first molding 13. In some embodiments, a width W31 of the first RDL 31 is substantially equal to a width W13 of the first molding 13.

In some embodiments, a second RDL 15 is disposed over the first die 11, the first bump 12, the first molding 13 and the first via 14. In some embodiments, the second RDL 15 forms at the first side 10a of the first semiconductor structure 10. In some embodiments, the first via 14 extends between the first RDL 31 and the second RDL 15. In some embodiments, a width W15 of the second RDL 15 is substantially equal to the width W13 of the first molding 13.

In some embodiments, the semiconductor package 100 includes a plurality of connectors 16 disposed on the first side 10a of the first semiconductor structure 10. The first semiconductor structure 10 may be probed through the connectors 16 before the second semiconductor structure 20 is electrically connected to the first semiconductor structure 10.

Each of the plurality of connectors 16 is electrically connected by the second RDL 15 to at least one of the first bump 12 and at least one of the first via 14. In some embodiments, the first semiconductor structure 10 is electrically connected to the second semiconductor structure 20 through the plurality of connectors 16. In some embodiments, the plurality of connectors 16 includes a first bump connector 161 and a first via connector 162, wherein the first bump connector 161 and the first via connector 162 are electrically connected to the first bump 12 and the first via 14. In some embodiments, the plurality of connectors 16 further includes a second bump connector 163 disposed adjacent to the first bump connector 161. In some embodiments, the first bump connector 161 is disposed between the first via connector 162 and the second bump connector 163.

In some embodiments, the first bump connector 161 includes a first bump conductive pillar 1611 disposed on the first side 10a of the first semiconductor structure 10, and a first bump solder member 1612 formed on the first bump conductive pillar 1611. In some embodiments, the first bump conductive pillar 1611 is exposed in order to electrically connect to the second semiconductor structure 20. In some embodiments, the first bump conductive pillar 1611 is bonded to the second semiconductor structure 20 by the first bump solder member 1612. In some embodiments, the first bump connector 161 is electrically connected to the first bump pad 121 and the first through via 141.

In some embodiments, the first via connector 162 includes a first via conductive pillar 1621 disposed on the first side 10a of the first semiconductor structure 10, and a first via solder member 1622 formed on the first via conductive pillar 1621. In some embodiments, the first via conductive pillar 1621 is exposed in order to electrically connect to the second semiconductor structure 20. In some embodiments, the first via conductive pillar 1621 is bonded to the second semiconductor structure 20 by the first via solder member 1622. In some embodiments, the first via connector 162 is electrically connected to the second bump pad 122 and the second through via 142.

In some embodiments, the second bump connector 163 is electrically connected to the second bump pad 122 and the first through via 141. In some embodiments, the second bump connector 163 is electrically connected to the second via 112.

In some embodiments, the second RDL 15 is disposed between the plurality of connectors 16 and the first bump 12. In some embodiments, the first bump connector 161 and the first via connector 162 are electrically connected to the first bump 12 and the first via 14 through the second RDL 15. In some embodiments, the second bump connector 163 is electrically connected to the first bump 12 and the first via 14 through the second RDL 15.

In some embodiments, the second semiconductor structure 20 includes a second die 21. In some embodiments, the second die 21 is electrically connected to the first die 11 through the first bump connector 161, the second RDL 15 and the first bump 12. In some embodiments, at least a portion of the second die 21 overlaps the first die 11 from a top view perspective. In some embodiments, the second die 21 is a logic die, which may be a central processing unit (CPU) die, a micro-control unit (MCU) die, an input-output (IO) die, a baseband (BB) die, an application processor (AP) die, or the like. In some embodiments, the second die 21 is a memory die such as a dynamic random-access memory (DRAM) die or a static random-access memory (SRAM) die, or may be another type of die.

In some embodiments, the second semiconductor structure 20 includes a plurality of second dies 21 adjacent to each other. In some embodiments, each of the second dies 21 includes a plurality of second bumps 22 disposed over and electrically connected to the second die 21. Each of the second bumps 22 is electrically connected to a circuitry or an electrical component disposed over or within the corresponding second die 21. In some embodiments, the second bumps 22 are electrically connected to the first bump connector 161 and the second bump connector 163.

In some embodiments, the second semiconductor structure 20 further includes a second molding 23 surrounding the second die 21, the second bumps 22, and the plurality of connectors 16. In some embodiments, the second RDL 15 is disposed between the first molding 13 and the second molding 23. In some embodiments, a width W23 of the second molding 23 is substantially equal to the width W13 of the first molding 13.

In some embodiments, the second semiconductor structure 20 further includes an underfill 24 surrounding the first bump connector 161, the first via connector 162 and the second bump 22. In some embodiments, the underfill 24 is disposed between the first bump 12 and the second die 21, and between the first via 14 and the second die 21. In some embodiments, the underfill 24 is disposed between the second RDL 15 and the second die 12. In some embodiments, the second molding 23 surrounds the underfill 24.

In some embodiments, a plurality of conductive bumps 321, 322 are disposed under the first RDL 31 and electrically connected to the first RDL 31, the first die 11 and the second die 21. In some embodiments, the conductive bumps 321, 322 are solder bumps.

In some embodiments, referring to FIG. 1, a plurality of first bump conductive pillar 1611 and a plurality of first via conductive pillar 1621 are disposed at the peripheral portion of the semiconductor package 100. In some embodiments, the plurality of first bump conductive pillar 1611 and the plurality of first via conductive pillar 1621 surround the first die 11 and the second die 21 from a top view perspective. In some embodiments, some of the plurality of first bump conductive pillar 1611 and some of the plurality of first via conductive pillar 1621 are disposed between the plurality of first dies 11 from a top view perspective. In some embodiments, some of the plurality of first bump conductive pillar 1611 and some of the plurality of first via conductive pillar 1621 form a group of connectors 17, the semiconductor package 100 includes a plurality of groups of connectors 17, and the groups of connectors 17 are separated from each other and disposed at the peripheral portion of the semiconductor package 100. In some embodiments, some of the groups of connectors 17 are disposed between the plurality of first dies 11 from a top view perspective.

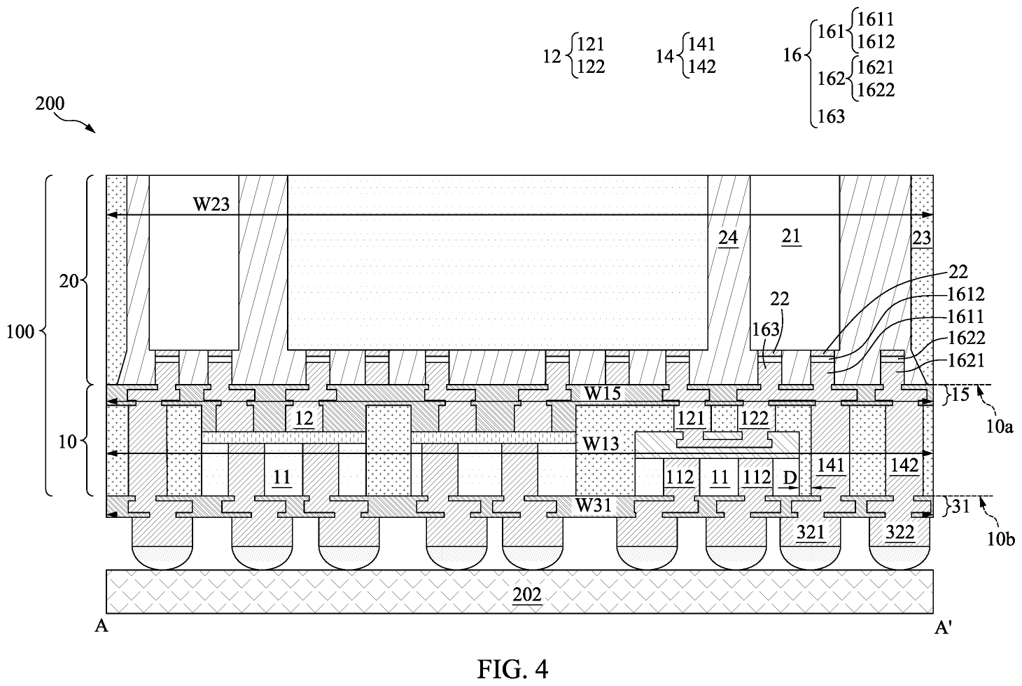

Referring to FIG. 4, a semiconductor package 200 includes a substrate 202 and the semiconductor package 100 mounted on the substrate 202. In some embodiments, the semiconductor package 200 is a CoWoS structure.

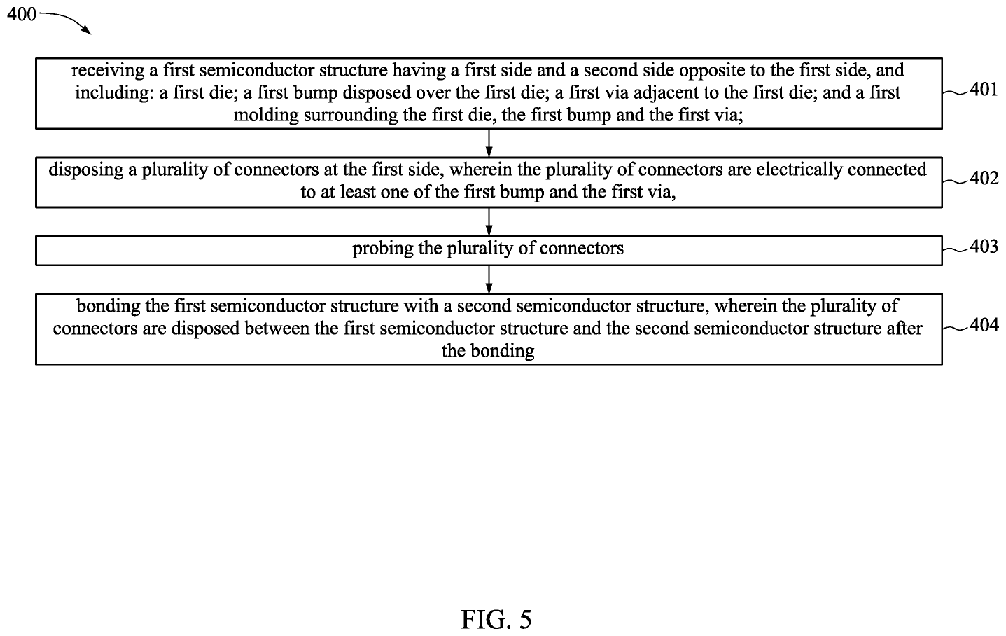

According to some embodiments of the present disclosure, a method for manufacturing and testing a semiconductor structure is disclosed. In some embodiments, a semiconductor package 100 is fabricated by a method 400, and a first semiconductor structure 10 and a second semiconductor structure 20 are tested by the method 400. FIG. 5 is a flowchart of the method 400 in accordance with some embodiments. The method 400 includes a number of operations (401 to 404), and descriptions and illustrations are not deemed as a limitation to a sequence of the operations. Additional steps can be provided before, during, and after the operations shown in FIG. 5, and some of the operations described below can be replaced or eliminated in other embodiments of the method 400. An order of the operations may be interchangeable.

In operation 401, referring to FIG. 5, a first semiconductor structure is received, wherein the first semiconductor structure has a first side and a second side opposite to the first side, and includes: a first die; a first bump disposed over the first die; a first via adjacent to the first die; and a first molding surrounding the first die, the first bump and the first via. In operation 402, a plurality of connectors are disposed on the first side, wherein the plurality of connectors are electrically connected to at least one of the first bump and the first via. In operation 403, the plurality of connectors are probed. In operation 404, the first semiconductor structure is bonded to a second semiconductor structure, wherein the plurality of connectors are disposed between the first semiconductor structure and the second semiconductor structure after the bonding.

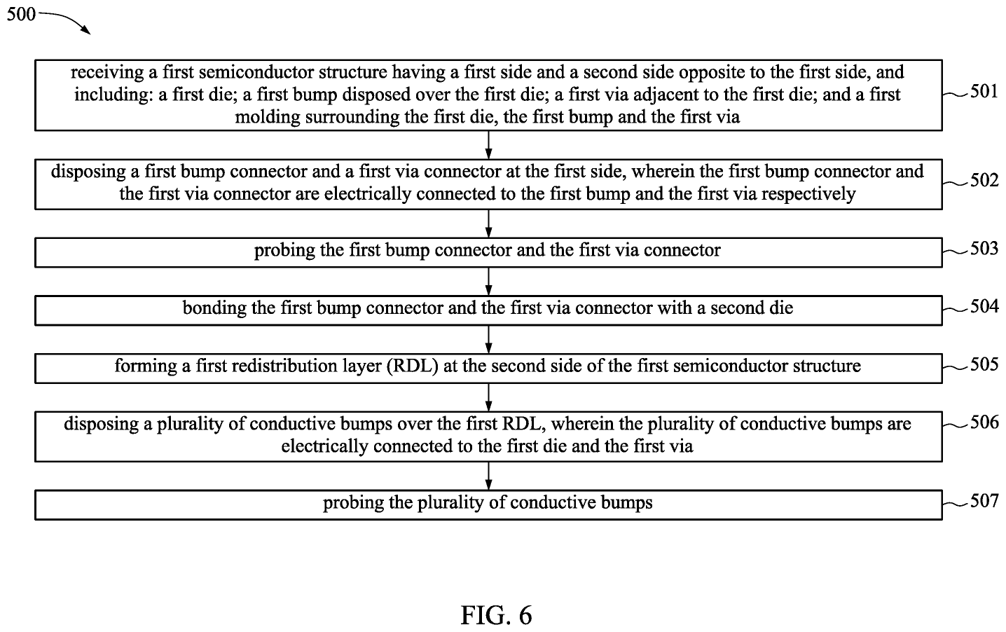

According to some embodiments of the present disclosure, another method for manufacturing and testing a semiconductor structure is disclosed. In some embodiments, a semiconductor package 100 is fabricated by a method 500, and a first semiconductor package 100 and a second semiconductor structure 200 are tested by the method 500. FIG. 6 is a flowchart of the method 500 in accordance with some embodiments. The method 500 includes a number of operations (501 to 507), and descriptions and illustrations are not deemed as a limitation to a sequence of the operations. Additional steps can be provided before, during, and after the operations shown in FIG. 6, and some of the operations described below can be replaced or eliminated in other embodiments of the method 500. An order of the operations may be interchangeable.

In operation 501, referring to FIG. 6, a first semiconductor structure having a first side and a second side opposite to the first side is received, wherein the first semiconductor structure includes: a first die; a first bump disposed over the first die; a first via adjacent to the first die; and a first molding surrounding the first die, the first bump and the first via. In operation 502, a first bump connector and a first via connector are disposed on the first side, wherein the first bump connector and the first via connector are electrically connected to the first bump and the first via, respectively. In operation 503, the first bump connector and the first via connector are probed. In operation 504, the first bump connector and the first via connector are bonded to a second die. In operation 505, a first redistribution layer (RDL) is formed on the second side of the first semiconductor structure. In operation 506, a plurality of conductive bumps are disposed over the first RDL, wherein the plurality of conductive bumps are electrically connected to the first die and the first via. In operation 507, the plurality of conductive bumps are probed.

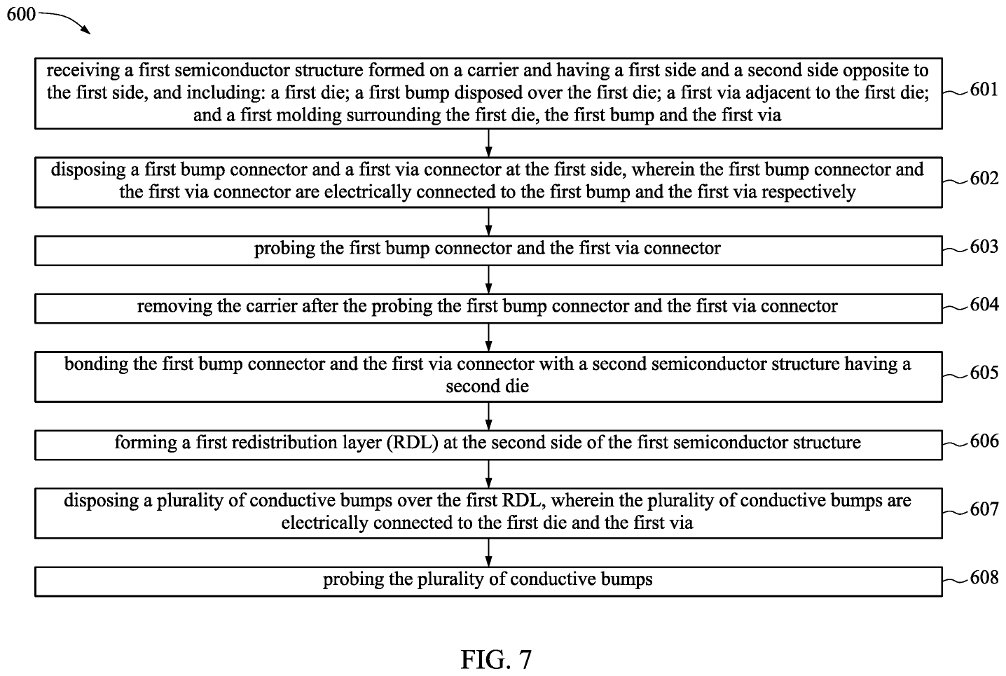

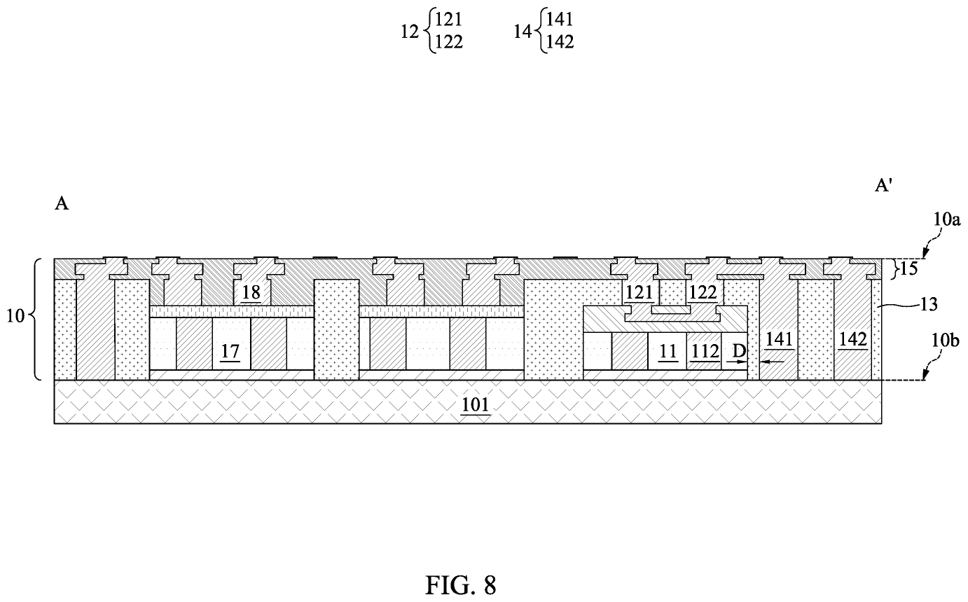

According to some embodiments of the present disclosure, another method for manufacturing and testing a semiconductor structure is disclosed. In some embodiments, a semiconductor package 100 is fabricated by a method 600, and a first semiconductor structure 10 and a second semiconductor structure 20 are tested by the method 600. FIG. 7 is a flowchart of the method 600 in accordance with some embodiments. The method 600 includes a number of operations (601 to 608), and descriptions and illustrations are not deemed as a limitation to a sequence of the operations. Additional steps can be provided before, during, and after the operations shown in FIG. 7, and some of the operations described below can be replaced or eliminated in other embodiments of the method 600. An order of the operations may be interchangeable. FIGS. 8 to 18 are schematic cross-sectional views of one or more operations of the method 600 for manufacturing a semiconductor structure in accordance with some embodiments of the present disclosure.

The method 600 begins with operation 601. Referring to FIG. 8, operation 401 includes receiving a first semiconductor structure 10, wherein the first semiconductor structure 10 is formed on a carrier substrate 101 and includes a first side 10a and a second side 10b opposite to the first side 10a. In some embodiments, the first semiconductor structure 10 further includes: a first die 11; a first bump 12 disposed over the first die 11; a first via 14 adjacent to the first die 11; and a first molding 13 surrounding the first die 11, the first bump 12 and the first via 14. In some embodiments, a plurality of first bumps 12, such as a first bump pad 121 and the second bump pad 122, are disposed over the first die 11. In some embodiments, the first via 14 includes a first through via 141 and a second through via 142. In some embodiments, the first semiconductor structure 10 shown in FIG. 2 is formed. In some embodiments, the first molding 13 is formed by disposing a molding material over a carrier substrate 101, wherein the first molding 13 encapsulates the first die 11, the first bump 12 and the first via 14. In some embodiments, the molding material includes molding compound, epoxy or any other suitable material. In some embodiments, the molding material is disposed by compression molding, transfer molding or any other suitable operations.

In some embodiments, a second RDL 15 is formed on the first bump 12, the first molding 13 and the first via 14, and a top surface of the second RDL 15 is defined as the first side 10a of the first semiconductor structure 10. In some embodiments, the first die 11 includes one or more circuitries or electrical components electrically connected to the corresponding first bumps 12.

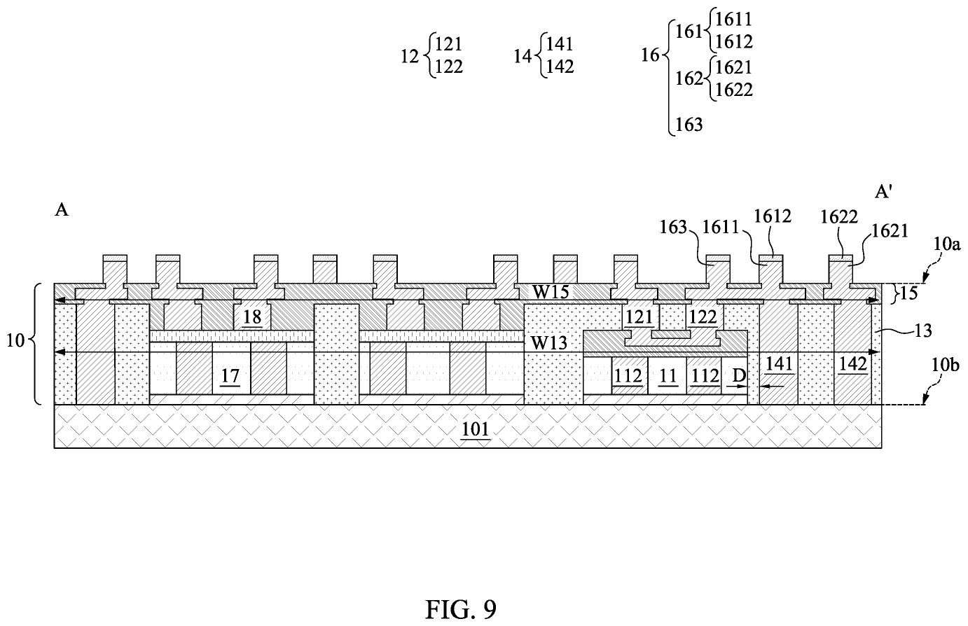

The method 600 continues with operation 602. Referring to FIG. 9, operation 602 includes disposing a first bump connector 161, a first via connector 162, and the second bump connector 163 on the first side 10a, wherein the first bump connector 161, the first via connector 162, and the second bump connector 163 are electrically connected to the first bump 12 and the first via 14, respectively. In some embodiments, the first bump connector 161, the first via connector 162, and the second bump connector 163 are exposed through and protrude from the first semiconductor structure 10. In some embodiments, the first bump connector 161, the first via connector 162, and the second bump connector 163 are formed on the second RDL 15.

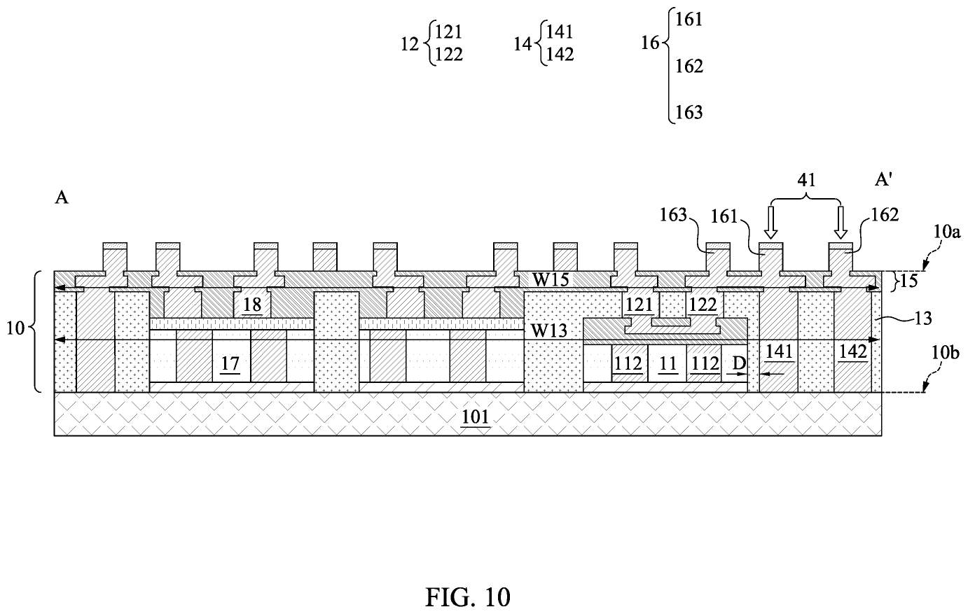

The method 600 continues with operation 603. Referring to FIG. 10, operation 603 includes probing the first bump connector 161 and the first via connector 162. In some embodiments, the probing includes supplying a voltage between connectors 16, such as between the first bump connector 161 and the first via connector 162.

FIG. 10 also illustrates the probing of the first semiconductor structure 10 and the first die 11 through the first bump connector 161 and the first via connector 162, wherein arrows 41 represent probe pins that are used for the probing. It should be noted that the first die 11 may be a known-good die after the probing. Additional defects, however, may be introduced, for example, in electrical paths between the first die 11 and the connectors 16. The first semiconductor structure 10 may pass a probe test and be marked as a good package, or the first semiconductor structure 10 may fail the probe test and be marked as defective. Therefore, through the probing, the good packages and the defective packages may be identified.

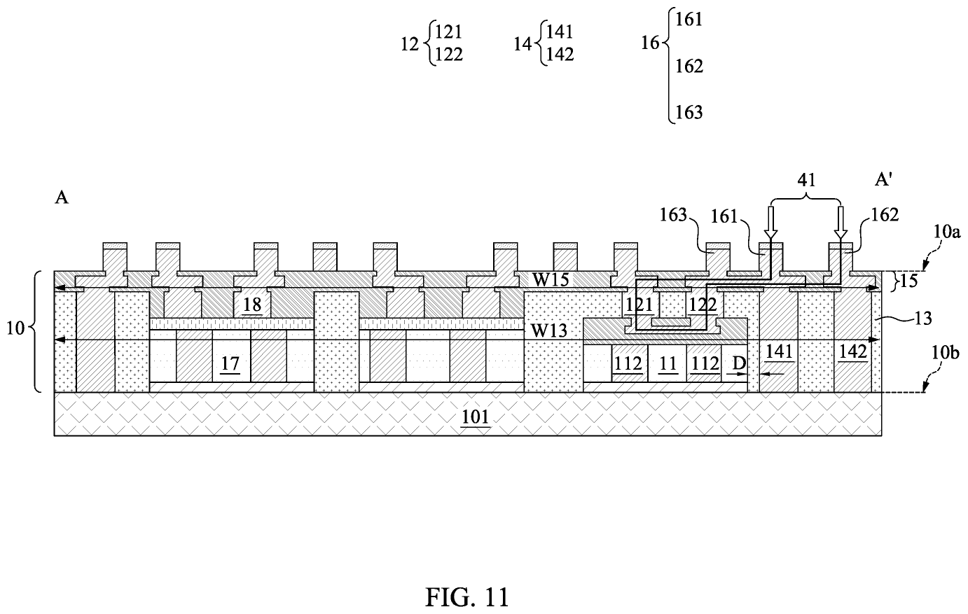

In some embodiments, referring to FIG. 11, during probing, the voltage is supplied between the first bump connector 161 and the first via connector 162 for current (e.g. testing signal) flowing, such that the may flow through the second RDL 15, the first bump pad 121 and the second bump pad 122. In some embodiments, the current does not flow into the first die 11. In some embodiments, the voltage is supplied between the first bump connector 161 and the first via connector 162 flowing via the first bump 12 and the second RDL 15. In some embodiments, the current does not flow into the first die 11 and the first via 14.

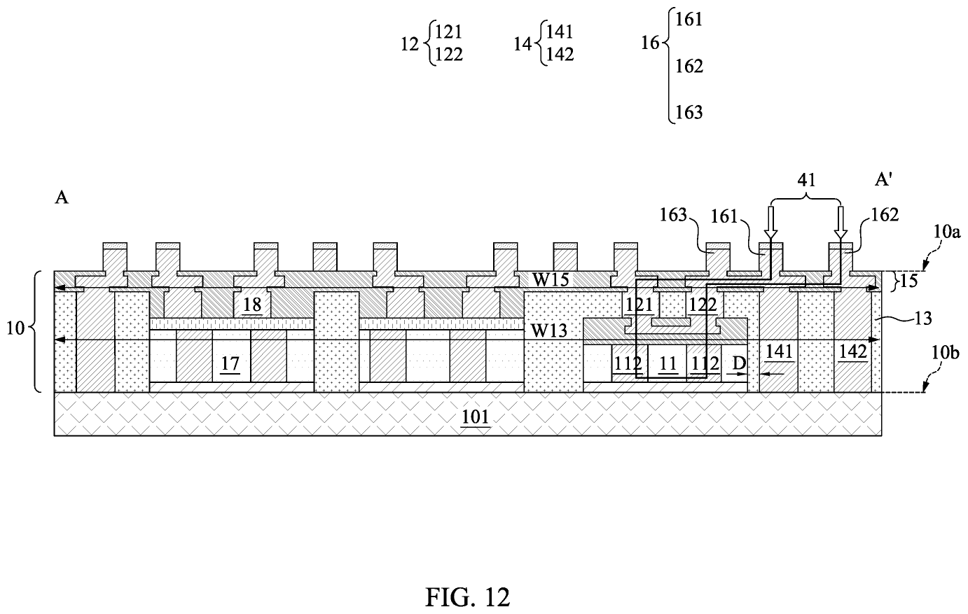

In some embodiments, referring to FIG. 12, during probing, the voltage is supplied between the first bump connector 161 and the first via connector 162 for current flowing, such that the current may flow through the second RDL 15, the first bump pad 121, the second bump pad 122, and the first die 11. In some embodiments, the voltage is supplied between the first bump connector 161 and the first via connector 162 for current flowing through the second RDL 15, the first bump 12 and the first die 11. In some embodiments, the current does not flow into the first via 14.

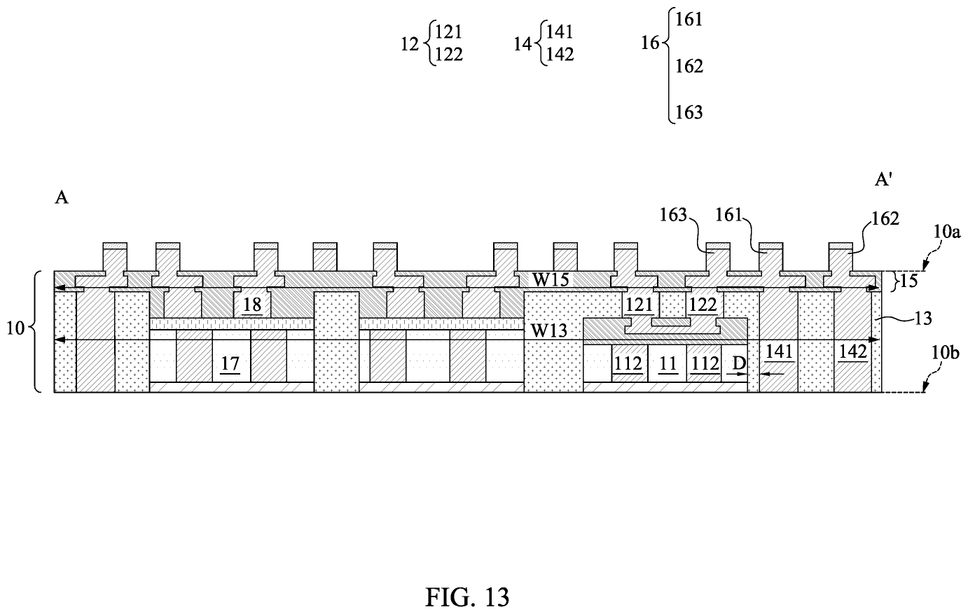

The method 600 continues with operation 604. Referring to FIG. 13, operation 604 includes removing the carrier substrate 101 after the probing of the first bump connector 161 and the first via connector 162. In some embodiments, the method 600 further includes detaching the carrier substrate 101 from the first die 11 and the first molding 13 to form the first semiconductor structure 10. In some embodiments, the carrier substrate 101 is de-bonded from the first semiconductor structure 10. In some embodiments, one end of the first via 14 is exposed after the carrier substrate 101 is removed. In some embodiments, the first die 11 and the first via 14 are temporarily attached to the carrier substrate 101 for further processing as shown in FIGS. 8 to 13. In some embodiments, the carrier substrate 101 is subsequently removed from the first semiconductor structure 10 and therefore is omitted from the semiconductor package 100 as shown in FIG. 3.

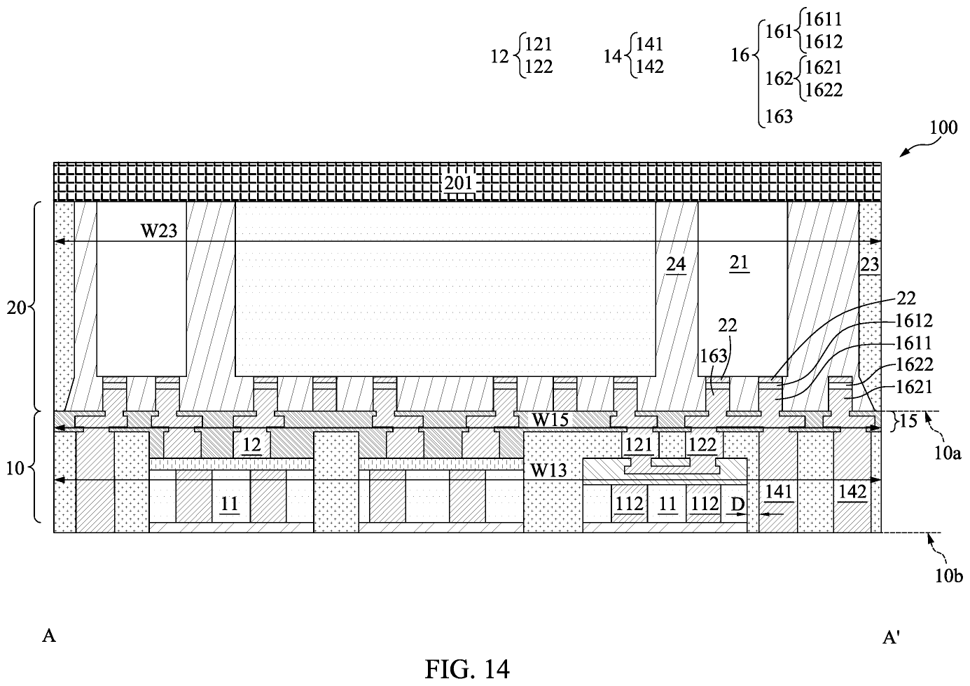

The method 600 continues with operation 605. Referring to FIG. 14, operation 605 includes bonding the first bump connector 161, the first via connector 162 and the second bump connector 163 to a second semiconductor structure 20 having a second die 21.

In some embodiments, the first bump connector 161 and the second bump connector 163 are disposed between the first semiconductor structure 10 and the second die 21 after the bonding of first semiconductor structure 10 to the second semiconductor structure 20. In some embodiments, the second semiconductor structure 20 is formed before being bonded to the first semiconductor structure 10. In some embodiments, the second semiconductor structure 20 includes the second die 21 having a plurality of second bumps 22, an underfill 24, a second molding 23 and a substrate 201. In some embodiments, the second die 21 is disposed over and electrically connected to the first bump connector 161, the second bump connector 163 and the first semiconductor structure 10 through the second bump 22. In some embodiments, the second semiconductor structure 20 shown in FIG. 3 and the first semiconductor structure 10 are bonded to each other.

In some embodiments, the substrate 201 is attached to the second molding 23 and the second die 21. In some embodiments, the substrate 201 is in contact with the underfill 24. In some embodiments, the underfill 24 is formed to surround the second bump 22, the first bump connector 161, the first via connector 162 and the second bump connector 163. In some embodiments, the underfill 24 is in contact with the second die 21. In some embodiments, the second molding 23 is formed to surround the second die 21, the second bump 22, and the underfill 24. In some embodiments, at least a portion of the underfill 24 is disposed between the plurality of second dies 21. In some embodiments, the second molding 23 and the underfill 24 are in contact with the first semiconductor structure 10.

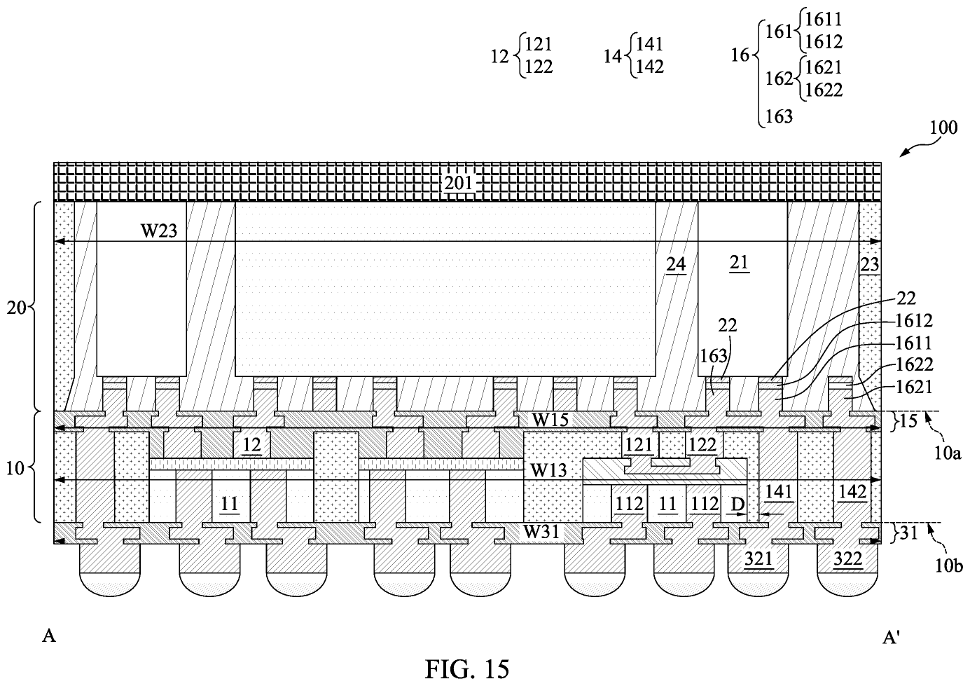

The method 600 continues with operation 606. Referring to FIG. 15, operation 606 includes forming a first RDL 31 on the second side 10b of the first semiconductor structure 10. The first RDL 31 is formed covering the first die 11, the first via 14 and the first molding 13.

The method 600 continues with operation 607. Operation 607 includes disposing a plurality of conductive bumps 321, 322 over the first RDL 31, wherein each of the plurality of conductive bumps 321, 322 is electrically connected to one or more of the first die 11 and the first via 14. In some embodiments, the plurality of conductive bumps 321, 322 are solder bumps formed by ball dropping, electroplating or any other suitable operations. In some embodiments, after the plurality of conductive bumps 321, 322 are disposed over the first RDL 31, the completed semiconductor package 100 is provided, including the first RDL 31, the first semiconductor substrate 10 and the second semiconductor structure 20 stacked in sequence.

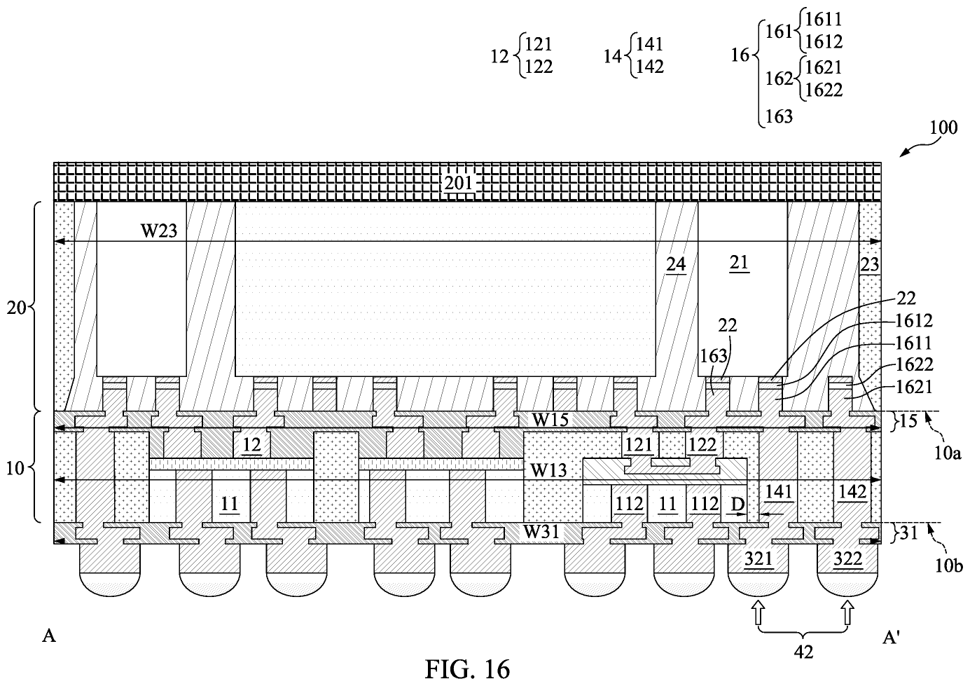

The method 600 continues with operation 608. Referring to FIG. 16, operation 608 includes probing the plurality of conductive bumps 321, 322. In some embodiments, the probing of the plurality of conductive bumps 321, 322 includes supplying a voltage between at least two of the plurality of conductive bumps 321, 322.

FIG. 16 also illustrates the probing of the semiconductor package 100 through at least two of the plurality of conductive bumps 321, 322, wherein arrows 42 represent probe pins that are used for the probing. It should be noted that the first die 11 and the second die 21 may be known-good dies after the probing. Additional defects, however, may be introduced, for example, in electrical paths between the second die 11 and the plurality of conductive bumps 321, 322. The semiconductor package 100 may pass the probe test and be marked as a good package, or the semiconductor package 100 may fail the probe test and be marked as defective. Therefore, through the probing, the good packages and the defective packages may be identified.

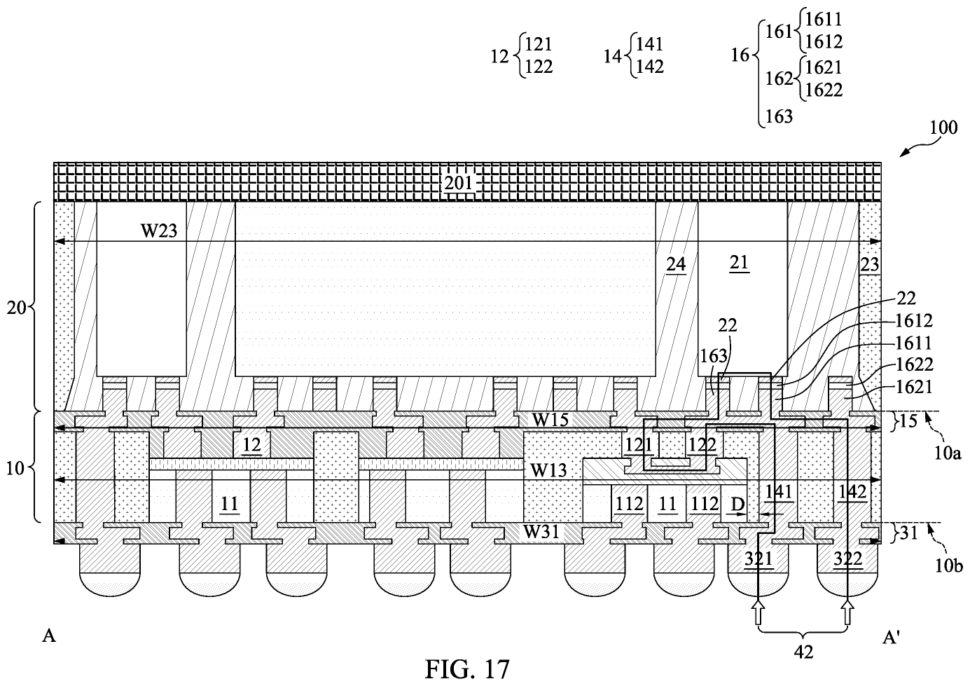

In some embodiments, referring to FIG. 17, during probing, the voltage is supplied between the at least two of the plurality of conductive bumps 321, 322, such that the current may flow through the first RDL 31, the first through via 141 and the second through via 142, the first bump pad 121, the second bump pad 122, the first bump connector 161, the second bump connector 163, the second bumps 22 and the second die 21. In some embodiments, the current does not flow into the first die 11.

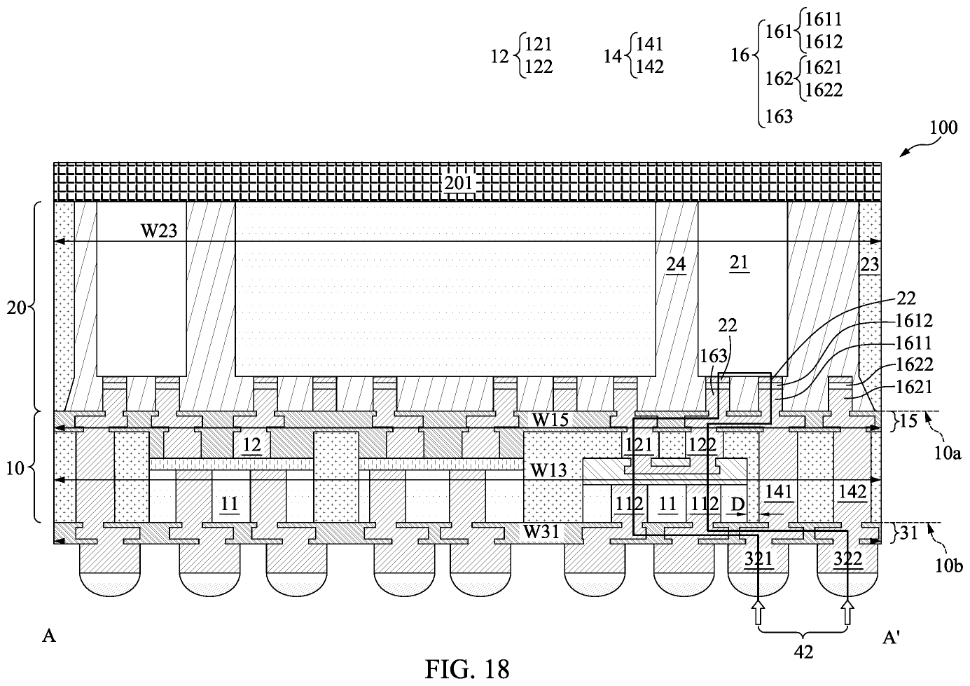

In some embodiments, referring to FIG. 18, during probing, the voltage is supplied between the at least two of the plurality of conductive bumps 321, 322, such that the current may flow through the first RDL 31, the second via 112 of the first die 11, the first bump pad 121, the second bump pad 122, the first bump connector 161, the second bump connector 163, the second bumps 22 and the second die 21. In some embodiments, the current does not flow into the first via 14.

One aspect of this disclosure relates to a method for manufacturing and testing a semiconductor package. The method includes receiving a first semiconductor structure having a first side and a second side opposite to the first side, wherein the first semiconductor structure includes: a first die; a first bump disposed over the first die; a first via adjacent to the first die; and a first molding surrounding the first die, the first bump and the first via. The method further includes disposing a plurality of connectors on the first side, wherein each of the plurality of connectors is electrically connected to at least one of the first bump and the first via; probing the plurality of connectors; and bonding the first semiconductor structure to a second semiconductor structure, wherein the plurality of connectors are disposed between the first semiconductor structure and the second semiconductor structure after the bonding.

In some embodiments, the method further includes forming a first redistribution layer (RDL) on the second side of the first semiconductor structure; disposing a plurality of conductive bumps over the first RDL, wherein each of the plurality of conductive bumps is electrically connected to at least one of the first die and the first via; and probing the plurality of conductive bumps. In some embodiments, the probing of the plurality of conductive bumps includes supplying a voltage between at least two of the plurality of conductive bumps. In some embodiments, the voltage is supplied between the at least two of the plurality of conductive bumps via the first RDL, the first via, the first bump, the plurality of connectors, and the second semiconductor structure. In some embodiments, the voltage is supplied between the at least two of the plurality of conductive bumps via the first RDL, the first die, the first bump, the plurality of connectors and the second semiconductor structure. In some embodiments, the plurality of connectors includes a first bump connector and a first via connector, wherein the first bump connector and the first via connector are electrically connected to the first bump and the first via, respectively. In some embodiments, the probing includes supplying a voltage between the first bump connector and the first via connector. In some embodiments, the voltage is supplied between the first bump connector and the first via connector for current flowing via the first via, the first bump and the first die. In some embodiments, the voltage is supplied between the first bump connector and the first via connector for current flowing via the first bump and the first die. In some embodiments, the second semiconductor structure includes a second die and a second molding surrounding the second die and the plurality of connectors. In some embodiments, the method further includes forming a second RDL between the plurality of connectors and the first bump.

One aspect of this disclosure relates to a method for manufacturing and testing a semiconductor package. The method includes receiving a first semiconductor structure having a first side and a second side opposite to the first side, wherein the first semiconductor structure includes: a first die; a first bump disposed over the first die; a first via adjacent to the first die; and a first molding surrounding the first die, the first bump and the first via. The method further includes disposing a first bump connector and a first via connector on the first side, wherein the first bump connector and the first via connector are electrically connected to the first bump and the first via, respectively; probing the first bump connector and the first via connector; bonding the first bump connector and the first via connector to a second die; forming a first redistribution layer (RDL) on the second side of the first semiconductor structure; disposing a plurality of conductive bumps over the first RDL, wherein each of the plurality of conductive bumps is electrically connected to at least one of the first die and the first via; and probing the plurality of conductive bumps.

In some embodiments, the first bump connector and the first via connector are disposed between the first semiconductor structure and the second die after the bonding of the first bump connector and the first via connector to the second die. In some embodiments, the plurality of conductive bumps surround the first die and the second die from a top view perspective. In some embodiments, the first semiconductor structure is an interposer. In some embodiments, the method further includes forming the first semiconductor structure on a carrier before the disposing of the first bump connector and the first via connector; and removing the carrier after the probing the first bump connector and the first via connector.

An aspect of this disclosure relates to a semiconductor package. The semiconductor package includes a first die disposed over a first surface of a first redistribution layer (RDL); a first bump disposed over the first die; a first via disposed over the first RDL and adjacent to the first die and the first bump; a first molding disposed over the first RDL and surrounding the first die, the first bump and the first via; a first bump connector disposed over and electrically connected to the first bump; a first via connector disposed over and electrically connected to the first via; a second die disposed over and electrically connected to the first bump connector and the first via connector; a second molding disposed over the first molding and surrounding the second die, the first bump connector and the first via connector; and a plurality of conductive bumps disposed on a second surface of the first RDL opposite to the first surface of the first RDL and electrically connected to the first RDL, the first die and the second die.

In some embodiments, the semiconductor package further includes an underfill surrounding the first bump connector and the first via connector, wherein the underfill is disposed between the first bump and the second die and between the first via and the second die. In some embodiments, the semiconductor package further includes a second RDL between the first bump connector and the first bump and between the first via and the first via connector, wherein the first via extends between the first RDL and the second RDL. In some embodiments, a distance between the first die and the first via is greater than 350 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing and testing a semiconductor package, the method comprising:
receiving a first semiconductor structure having a first side and a second side opposite to the first side, and including:
a first die;
a first bump disposed over the first die;
a first via adjacent to the first die; and
a first molding surrounding the first die, the first bump and the first via;
disposing a plurality of connectors on the first side, wherein each of the plurality of connectors is electrically connected to at least one of the first bump and the first via;
probing the plurality of connectors; and
bonding the first semiconductor structure to a second semiconductor structure,
wherein the plurality of connectors are disposed between the first semiconductor structure and the second semiconductor structure after the bonding.

2. The method of claim 1, further comprising:
forming a first redistribution layer (RDL) on the second side of the first semiconductor structure;
disposing a plurality of conductive bumps over the first RDL, wherein each of the plurality of conductive bumps is electrically connected to at least one of the first die and the first via; and
probing the plurality of conductive bumps.

3. The method of claim 2, wherein the probing of the plurality of conductive bumps includes supplying a voltage between at least two of the plurality of conductive bumps.

4. The method of claim 3, wherein the voltage is supplied between the at least two of the plurality of conductive bumps via the first RDL, the first via, the first bump, the plurality of connectors, and the second semiconductor structure.

5. The method of claim 3, wherein the voltage is supplied between the at least two of the plurality of conductive bumps via the first RDL, the first die, the first bump, the plurality of connectors, and the second semiconductor structure.

6. The method of claim 1, wherein the plurality of connectors includes a first bump connector and a first via connector, wherein the first bump connector and the first via connector are electrically connected to the first bump and the first via respectively.

7. The method of claim 6, wherein the probing includes supplying a voltage between the first bump connector and the first via connector.

8. The method of claim 7, wherein the voltage is supplied between the first bump connector and the first via connector for current flowing via the first via, the first bump and the first die.

9. The method of claim 7, wherein the voltage is supplied between the first bump connector and the first via connector for current flowing via the first bump and the first die.

10. The method of claim 1, wherein the second semiconductor structure includes a second die and a second molding surrounding the second die and the plurality of connectors.

11. The method of claim 1, further comprising:
forming a second RDL between the plurality of connectors and the first bump.

12. A method for manufacturing and testing a semiconductor package, the method comprising:
receiving a first semiconductor structure having a first side and a second side opposite to the first side, and including:
a first die;
a first bump disposed over the first die;
a first via adjacent to the first die; and
a first molding surrounding the first die, the first bump and the first via;
disposing a first bump connector and a first via connector on the first side, wherein the first bump connector and the first via connector are electrically connected to the first bump and the first via, respectively;
probing the first bump connector and the first via connector;
bonding the first bump connector and the first via connector to a second die;
forming a first redistribution layer (RDL) on the second side of the first semiconductor structure;
disposing a plurality of conductive bumps over the first RDL, wherein each of the plurality of conductive bumps is electrically connected to the first die or the first via; and
probing the plurality of conductive bumps.

13. The method of claim 12, wherein the first bump connector and the first via connector are disposed between the first semiconductor structure and the second die after the bonding of the first bump connector and the first via connector to the second die.

14. The method of claim 12, wherein the plurality of conductive bumps surround the first die and the second die from a top view perspective.

15. The method of claim 12, wherein the first semiconductor structure is an interposer.

16. The method of claim 12, further comprising:
forming the first semiconductor structure on a carrier before the disposing of the first bump connector and the first via connector; and
removing the carrier after the probing of the first bump connector and the first via connector.

17. A semiconductor package, comprising:
a first die disposed over a first surface of a first redistribution layer (RDL);
a first bump disposed over the first die;
a first via disposed over the first RDL and adjacent to the first die and the first bump;
a first molding disposed over the first RDL and surrounding the first die, the first bump and the first via;
a first bump connector disposed over and electrically connected to the first bump and the first via through a second redistribution layer (RDL);
a first via connector disposed over and electrically connected to the first via and the first bump through the second RDL;
a second die disposed over and electrically connected to the first bump connector and the first via connector;
a second molding disposed over the first molding and surrounding the second die, the first bump connector and the first via connector; and
a plurality of conductive bumps disposed on a second surface of the first RDL opposite to the first surface of the first RDL and electrically connected to the first RDL, the first die and the second die,
wherein the first bump connector and the first via connector are electrically connected to each other.

18. The semiconductor package of claim 17, further comprising an underfill surrounding the first bump connector and the first via connector, wherein the underfill is disposed between the first bump and the second die, and between the first via and the second die.

19. The semiconductor package of claim 17, further comprising:
a second RDL between the first bump connector and the first bump and between the first via and the first via connector,
wherein the first via extends between the first RDL and the second RDL.

20. The semiconductor package of claim 17, wherein a distance between the first die and the first via is greater than 350 nm.
